(19) United States
(12) Patent Application Publication
(10) Pub. No.: US 2026/0314095 A1
(43) Pub. Date: Oct. 8, 2026

(54) IMAGE SENSING DEVICE AND METHOD FOR MANUFACTURING THE SAME

(71) Applicant: SK hynix Inc., Icheon-si (KR)

(72) Inventor: Ji Suk PARK, Icheon-si (KR)

(21) Appl. No.: 19/345,300

(22) Filed: Sep. 30, 2025

(30) Foreign Application Priority Data
Apr. 2, 2025 (KR) 10-2025-0043019

(51) Int. Cl. H10F 39/00

(52) U.S. Cl. CPC H10F 39/8053; H10F 39/024; H10F 39/806; H10F 39/8063

(57) ABSTRACT

An image sensing device including an air grid is disclosed. The image sensing device includes a light guide layer including one or more first air grid structures disposed in an active pixel array and a light blocking structure disposed in an optical black pixel array; and a light filter layer including a second air grid structure that overlaps the one or more first air grid structures and is disposed between a plurality of color filters, and disposed on the light guide layer, wherein a height of an air region included in the one or more first air grid structures is equal to a height of the light blocking structure.

### CROSS-REFERENCE TO RELATED APPLICATION

This patent document claims the priority and benefits of Korean patent application No. 10-2025-0043019, filed on Apr. 2, 2025, the disclosure of which is incorporated herein by reference in its entirety as part of the disclosure of this patent document.

### TECHNICAL FIELD

The technology and implementations disclosed in this patent document generally relate to an image sensing device and a method for manufacturing the same, and more particularly to an image sensing device including an air grid and a method for manufacturing the same.

### BACKGROUND

An image sensing device captures optical images by converting light into electrical signals using a photosensitive semiconductor material that reacts to light. With advancements in industries such as automotive, medical, computer and communication industries, the demand for high-performance image sensing devices is growing across various fields such as smartphones, digital cameras, game machines, IoT (Internet of Things), robots, security cameras and medical micro cameras.

The image sensing device may be roughly divided into charge coupled device (CCD) image sensing devices and complementary metal oxide semiconductor (CMOS) image sensing devices. CCD image sensing devices offer a better image quality, but they tend to consume more power and are larger as compared to CMOS image sensing devices. CMOS image sensing devices are smaller in size and consume less power than CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to an image sensing device including a structure capable of addressing the challenge of forming an air grid for active pixels located in an edge region of an active pixel array. This challenge arises due to a step formed by a light blocking structure in a region adjacent to the light blocking structure formed in an optical black pixel array. Various embodiments of the disclosed technology also provide a method for manufacturing such an image sensing device.

In an embodiment of the disclosed technology, an image sensing device may include: an active pixel array region including an active pixel array of pixels; an optical black pixel array region including an optical black pixel array of pixels; a light guide layer including: one or more first air grid structures disposed in the active pixel array region; and a light blocking structure disposed in the optical black pixel array region; and a light filter layer including a second air grid structure that overlaps the one or more first air grid structures and disposed between a plurality of color filters, and disposed on the light guide layer, wherein each of the one or more first air grid structures includes an air region that is filled with air and surrounded by a material layer, wherein a height of the air region is equal to a height of the light blocking structure. In an example, the active pixel array may be configured to generate pixel signals in response to incident light, and the optical black pixel array may be configured to generate dark current and disposed adjacent to the active pixel array.

In some implementations, the light guide layer may further include: a first optical coating layer disposed between the one or more first air grid structures.

In some implementations, the first optical coating layer may be further arranged on the one or more first air grid structures, and may further extend above the light blocking structure.

In some implementations, the second air grid structure may be formed to be in contact with a top surface of the first optical coating layer.

In some implementations, the light filter layer may further include: a second optical coating layer in contact with a top surface of the first optical coating layer within the optical black pixel array and in contact with a top surface of each of the plurality of color filters within the active pixel array.

In some implementations, the material layer of the one or more first air grid structures may further include: a capping layer formed to surround a top surface and side surfaces of the air region, wherein the capping layer extends to be in contact with a top surface and side surfaces of the light blocking structure.

In some implementations, the material layer of the one or more first air grid structures may further include: a support layer covering the top surface of the capping layer and thicker than the capping layer, wherein the support layer extends along the top surface of the capping layer over the light blocking structure.

In some implementations, the first optical coating layer may have a higher refractive index than the capping layer.

In some implementations, the one or more first air grid structures may be disposed along one or more boundaries between a plurality of active pixels arranged in the active pixel array.

In some implementations, the light guide layer may be disposed on a back surface of a semiconductor substrate including a photoelectric conversion element.

In another embodiment of the disclosed technology, an image sensing device may include: a plurality of active pixels; a plurality of first air grid structures disposed at boundaries between the plurality of active pixels and including a first air region that is filled with air and surrounded by a material layer; a light blocking structure disposed at one side of the plurality of first air grid structures; and a plurality of second air grid structures disposed at the boundaries between the plurality of active pixels and including a second air region that is filled with air and surrounded by a material layer, the plurality of second air grid structures being disposed over the plurality of first air grid structures, wherein a top surface of the first air region is disposed on a same plane as a top surface of the light blocking structure. In an example, the plurality of active pixels may be configured to generate pixel signals in response to incident light.

In some implementations, the image sensing device may further include: a first optical coating layer disposed between the plurality of first air grid structures arranged at the boundaries between the active pixels; and a plurality of color filters, each color filter being disposed between the plurality of second air grid structures arranged at the boundaries of the plurality of active pixels.

In some implementations, the first optical coating layer may be further disposed on the plurality of first air grid structures, and may further extend above the light blocking structure.

In some implementations, the plurality of second air grid structures may be formed to be in contact with a top surface of the first optical coating layer.

In some implementations, the image sensing device may further include: a second optical coating layer formed to be in contact with top surfaces of the plurality of color filters, wherein the second optical coating layer further extends above the light blocking structure.

In some implementations, each of the plurality of first air grid structures may include: a first capping layer formed to surround a top surface and side surfaces of the first air region; and a first support layer formed to cover a top surface of the first capping layer, the first support layer being thicker than the first capping layer. Each of the plurality of second air grid structures may include: a second capping layer formed to surround a top surface and side surfaces of the second air region; and a second support layer formed to cover a top surface of the second capping layer, the second support layer being thicker than the second capping layer.

In some implementations, each of the first capping layer and the first support layer may have a lower refractive index than the first optical coating layer; and each of the second capping layer and the second support layer may have a lower refractive index than the color filters.

In some implementations, the plurality of first air grid structures may be disposed on a back surface of a semiconductor substrate including a photoelectric conversion element.

In another embodiment of the disclosed technology, a method for manufacturing an image sensing device may include: forming a light blocking structure in an optical black pixel array and a first sacrificial layer having a same height as the light blocking structure in an active pixel array adjacent to the optical black pixel array; etching a portion of the first sacrificial layer; forming a first capping layer formed to surround a top surface and side surfaces of the etched first sacrificial layer; forming at least one first support layer on the first capping layer; forming an optical coating layer formed to cover the first support layer; forming a second sacrificial layer on the optical coating layer; etching a portion of the second sacrificial layer; forming a second capping layer formed to surround a top surface and side surfaces of the etched second sacrificial layer; forming a second air region by removing the second sacrificial layer; and forming a second support layer on the second capping layer.

In some implementations, the forming the optical coating layer may include: filling a region between the first support layers with the optical coating layer; forming the optical coating layer to be higher than a top surface of the first support layer; and planarizing a top surface of the optical coating layer.

It is to be understood that both the foregoing general description and the following detailed description of the disclosed technology are illustrative and explanatory and are intended to provide further explanation of the disclosed technology as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some embodiments of the disclosed technology.

FIG. 2 is a plan view illustrating an example of a pixel array shown in FIG. 1 based on some embodiments of the disclosed technology.

FIG. 3 is a cross-sectional view illustrating an example of the pixel array taken along the line A-A′ shown in FIG. 2 based on some embodiments of the disclosed technology.

FIG. 4 is a flowchart illustrating an example of a method for manufacturing the image sensing device shown in FIG. 1 based on some embodiments of the disclosed technology.

FIGS. 5A to 5J are cross-sectional views illustrating examples of a method for manufacturing the image sensing device shown in FIG. 1 based on some embodiments of the disclosed technology.

### DETAILED DESCRIPTION

This patent document provides implementations and examples of an image sensing device including an air grid that may be used in configurations to substantially address one or more technical or engineering issues and to mitigate limitations or disadvantages encountered in some other image sensing devices. Some implementations of the disclosed technology relate to an image sensing device including a structure designed to overcome the difficulty of forming an air grid in the active pixels located in an edge region of an active pixel array. This difficulty arises due to a step or level difference caused by a light blocking structure located adjacent to the light blocking structure formed in an optical black pixel array. Some implementations of the disclosed technology relate to a method for manufacturing such an image sensing device. In recognition of the issues above, the disclosed technology may provide an image sensing device that enables the uniform formation of an air grid even in an active pixel array portion adjacent to the optical black pixel array, and a method for manufacturing the same.

Hereinafter, various implementations and embodiments of the disclosed technology are described with reference to the accompanying drawings. It should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

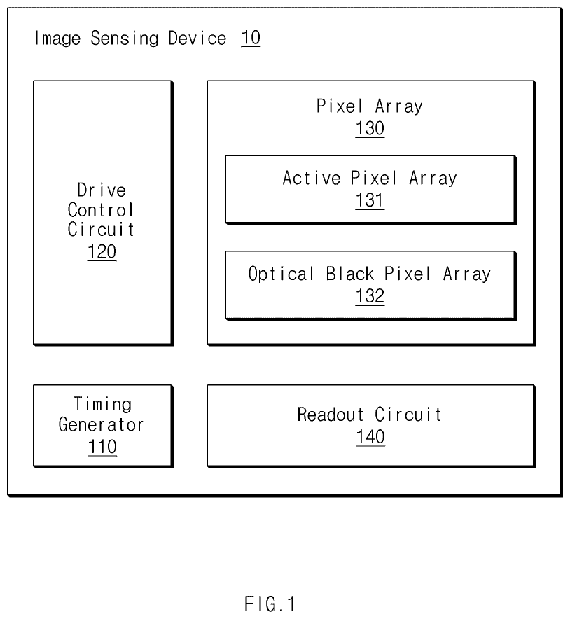

FIG. 1 is a schematic diagram illustrating an example of an image sensing device 10 based on some embodiments of the disclosed technology.

Referring to FIG. 1, the image sensing device 10 according to an exemplary embodiment of the disclosed technology may include a timing generator 110, a drive control circuit 120, a pixel array 130, and a readout circuit 140. The constituent components of the image sensing device 10 illustrated in FIG. 1 are discussed by way of example only, and this patent document encompasses numerous other changes, substitutions, variations, alterations, and modifications. In some embodiments described in this patent document, the word “pixel” can be used to indicate an image sensing pixel that is structured to detect incident light to generate electrical signals carrying images in the incident light. For example, the image sensing device 10 may be a Complementary Metal Oxide Semiconductor (CMOS) image sensor configured to convert incident light into an electrical signal.

The timing generator 110 may generate a timing signal to control the operations of the drive control circuit 120 and the readout circuit 140. In some implementations, the timing generator 110 may generate a timing signal in response to a request from an external processor (e.g., an image signal processor ISP). In some implementations, the timing generator 110 may include a logic control circuit, a phase-locked loop (PLL) circuit, a communication interface circuit, and the like.

The drive control circuit 120 may drive pixels (PXs) of the pixel array 130 in response to a timing signal output from the timing generator 110. The drive control circuit 120 may select and control pixels (PXs) included in at least one row line from among a plurality of row lines of the pixel array 130. The drive control circuit 120 may generate a row selection signal to select at least one row from among the plurality of rows. The drive control circuit 120 may sequentially enable a pixel reset signal and a transfer signal for pixels (PXs) corresponding to at least one selected row. Accordingly, an analog reference signal and an image signal generated from each of the pixels (PXs) of the selected row may be sequentially transmitted to the readout circuit 140. The reference signal may be an electrical signal provided to the readout circuit 140 when a floating diffusion (FD) region of each pixel is reset to a power-supply voltage (VDD). The image signal may be an electrical signal provided to the readout circuit 140 when photocharges generated by each pixel are accumulated in the floating diffusion (FD) region. The reference signal indicating unique pixel noise of each pixel, and the image signal indicating the intensity of incident light may be collectively referred to as a pixel signal as necessary.

The pixel array 130 may include a plurality of pixels (PXs) arranged in rows and columns. In one example, the plurality of pixels (PXs) can be arranged in a two-dimensional (2D) pixel array including rows and columns. The plurality of pixels may be connected to the drive control circuit 120 through a plurality of row lines extending in the row direction. The plurality of pixels may be connected to the readout circuit 140 through a plurality of column lines extending in the column direction. The plurality of pixels (PXs) may convert an optical signal into an electrical signal on a pixel basis or a pixel group basis, and may output a pixel signal. Here, the pixels in a pixel group of the pixel array 130 may share at least certain internal circuitry. The pixel array 130 may receive driving signals including a row selection signal, a pixel reset signal, a transfer signal, etc. from the drive control circuit 120. Upon receiving the driving signals, corresponding imaging pixels in the pixel array 130 may be activated to perform the operations corresponding to the row selection signal, the pixel reset signal, and the transfer signal.

The plurality of unit pixels included in the pixel array 130 may convert optical signals into electrical signals (pixel signals), and may be connected to a specific internal pixel circuit. The pixel array 130 may receive pixel control signals including a selection signal, a reset signal, a transfer signal, etc. from the drive control circuit 120. At least one pixel included in the row that is selected by the drive control circuit 120 according to the pixel control signal may perform a specific operation in response to the selection signal, the reset signal, and the transfer signal.

The pixel array 130 may include an active pixel array 131 and an optical black pixel array 132.

The active pixel array 131 may be a region that generates a pixel signal in response to incident light received from the outside. The optical black pixel array 132 may be a region that generates a dark signal that can be used to correct the dark noise of the active pixel array 131 that is associated with pixel output without receiving incident light. In some implementations, the term “optical black pixel array” can refer to a pixel array that includes non-imaging pixels such as dark pixels or reference pixels that is intentionally covered or shielded by an optically opaque structure or light blocking structure to block out light from reaching the covered or shielded photodiode elements of the dark pixels. In some implementations, the term “dark signal” can refer to signals or dark currents that generated by such non-imaging pixels due to factors other than light-induced charge carriers. Such a dark current generated by each black pixel is an electrical current that flows even in the absence of light. The dark signal can be used to correct errors in the pixel signal that are caused by dark current.

The active pixel array 131 may include a plurality of active pixels. Each of the plurality of the active pixels configured to generate pixel signals in response to incident light received by the pixels, respectively. In one embodiment in which the plurality of active pixels is arranged in a two-dimensional (2D) matrix configuration, the plurality of active pixels may be arranged in a row direction and a column direction.

The active pixel may generate a pixel signal in response to incident light. Among light incident upon the active pixel, light of a specific wavelength band (e.g., red light, green light, or blue light) may pass through an optical filter arranged in an active pixel, and light having penetrated the optical filter may be focused onto at least one photoelectric conversion element. The photoelectric conversion element may generate photocharges in response to incident light. An electrical signal may be generated by the pixel in response to the amount of generated photocharges.

The active pixel may generate a pixel signal even in a situation where the amount of incident light is minimal or absent (hereinafter referred to as a dark condition). A signal generated under the dark condition may be a signal corresponding to a noise component generated by the image sensing device 10. The noise component present in either the pixel signal generated by the active pixel under the dark condition or the dark signal generated by the optical black pixel may, for example, be referred to as dark noise. The optical black pixel are shielded from receiving light and are configured to generate black pixel signals representing dark currents generated without incident light.

Since the dark noise component is also present in the pixel signal generated by the active pixel under the light condition, a correction process for removing or reducing the dark noise component present in the pixel signal may be performed (hereinafter referred to as “correction for removing the dark noise component”). The correction for removing the dark noise component may be performed, for example, by the image signal processor (not shown).

The optical black pixel array 132 may be arranged adjacent to the active pixel array 131 within the pixel array 130. The optical black pixel array 132 may be, for example, a pixel region surrounding the active pixel array 131.

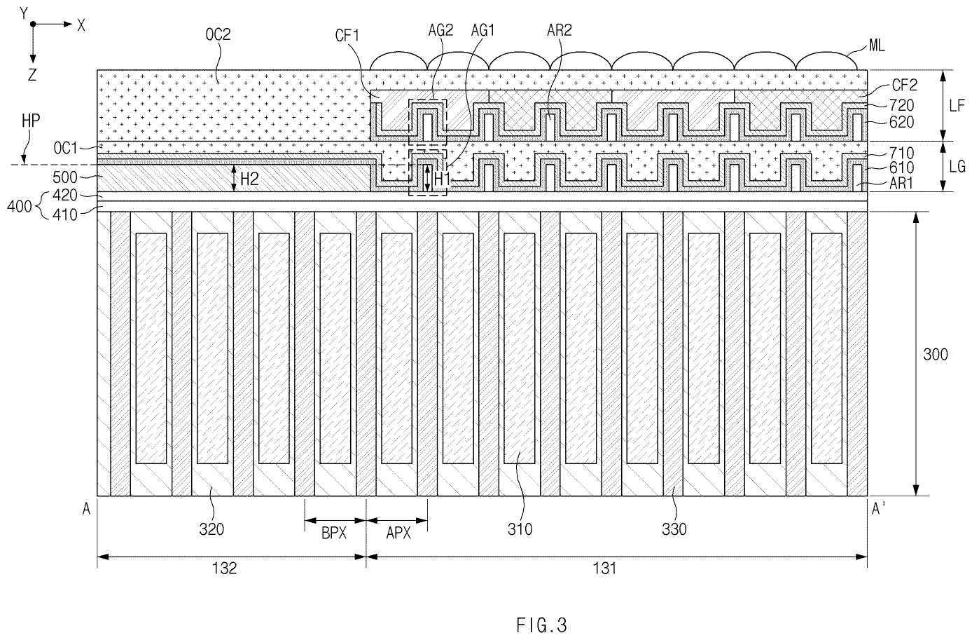

The optical black pixel array 132 may include a plurality of optical black pixels. Each of the plurality of the optical black pixels are shielded from receiving light and are configured to generate black pixel signals representing dark currents generated without incident light. The optical black pixel may have a structure similar to that of the active pixel, but may further include a light blocking structure 500 (see FIG. 3). The light blocking structure may include a material having a high light absorption rate or high light reflectivity. The light blocking structure may block incident light from entering a photoelectric conversion element within the optical black pixel. The optical black pixel may generate a dark signal. Since the optical black pixel includes the light blocking structure, the dark signal may refer to dark noise.

The readout circuit 140 may sample electrical signals output from the pixel array 130, may convert the electrical signals into digital signals, and may output the digital signals to the image signal processor. The readout circuit 140 may include, for example, a correlated double sampler (CDS), an analog-to-digital converter (ADC), an output buffer, a column driver, etc.

For example, the CDS may receive the reference signal and the image signal, each of which corresponds to the columns of the pixel array 130, and may sample signal levels of the reference signal and the image signal. In the image sensing device designed to use CMOS(s), the CDS may sample a pixel signal twice to remove a difference between these two samples, and may perform correlated double sampling to remove undesired offset values of pixels such as fixed noise. For example, the CDS may compare pixel output voltages obtained before and after photocharges generated by incident light are accumulated in the floating diffusion region to remove undesired offset values, enabling the measurement of the pixel output voltages based on the incident light.

The CDS may transmit reference signals and image signals, which are generated in each column based on a timing signal and a control signal of the timing controller, to the ADC as CDS signals.

For example, the ADC may convert an analog CDS signal received from the CDS into a digital signal, and may output the digital signal. The output buffer may temporarily hold and output the digital signal received from the ADC 140. A column driver may select a column from the output buffer based on the timing signal and the control signal of the timing generator 110, and may control the temporarily held digital signals to be output according to the selection order of columns

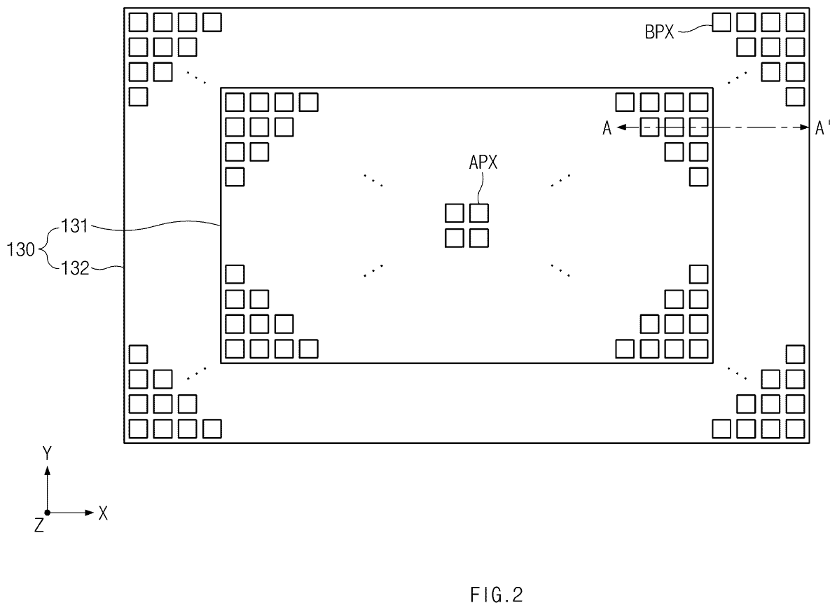

FIG. 2 is a plan view illustrating an example of the pixel array 130 shown in FIG. 1 based on some embodiments of the disclosed technology.

Referring to FIGS. 1 and 2, the pixel array 130 may include, for example, a structure in which a plurality of pixels is arranged in a two-dimensional structure. The pixel array 130 may include M pixels arranged in a first direction (X) (e.g., a row direction) (where ‘M’ is an integer greater than or equal to 2). The pixel array 130 may include N pixels arranged in a second direction (Y) (e.g., a column direction) (where ‘N’ is an integer greater than or equal to 2).

An active pixel array 131 may include a plurality of active pixels (APXs). The plurality of active pixels (APXs) may be arranged in a two-dimensional matrix configuration. The plurality of active pixels (APXs) may be repeatedly arranged in the first direction (X) and the second direction (Y). Each of the active pixels (APXs) may generate an electrical signal in response to incident light. For example, a predetermined photoelectric conversion element within the active pixel (APX) may generate photocharges in response to incident light. The generated photocharges may be converted into a pixel signal (or an electrical signal) by the predetermined pixel transistors, enabling the pixel signal to be output. The predetermined pixel transistors may include, for example, at least one of a transfer transistor, a reset transistor, a source follower transistor, and a selection transistor.

The transfer transistor may transfer the photocharges generated by the photoelectric conversion element to a floating diffusion (FD) region, the source follower transistor may output a pixel signal corresponding to the electric potential of the floating diffusion (FD) region, and the selection transistor may function as a switch to select one of the unit pixels (PX) to be used to output the pixel signal. The reset transistor may reset the electric potential of the floating diffusion (FD) region to a reference electric potential.

An optical black pixel array 132 may include a plurality of optical black pixels (BPXs). The plurality of optical black pixels (BPXs) may be repeatedly arranged in the first direction (X) and the second direction (Y) in an outer region of the active pixel array 131. Each of the optical black pixels (BPXs) may include a predetermined light blocking structure 500 (see FIG. 3) configured to block incident light. The optical black pixel (BPX) including the light blocking structure may output a signal for correcting a pixel signal output from the active pixel (APX).

The structure of each of the active pixel (APX) and the optical black pixel (BPX) will hereinafter be described with reference to FIG. 3 and below.

FIG. 3 is a cross-sectional view illustrating an example of the pixel array taken along the line A-A′ shown in FIG. 2 based on some embodiments of the disclosed technology.

Referring to FIGS. 2 and 3, a cross-section taken along the line A-A′ of FIG. 2 may include a semiconductor substrate 300, an anti-reflection region 400, a light guide layer (LG), a light filter layer (LF), and a plurality of microlenses (ML).

The semiconductor substrate 300 may include a photoelectric conversion element 310, a semiconductor region 320, and a pixel isolation structure 330. The semiconductor substrate 300 may include a back surface (e.g., a top surface of the semiconductor substrate 300 of FIG. 3) upon which light is incident and a front surface (e.g., a bottom surface of the semiconductor substrate 300 of FIG. 3) facing or opposite to the back surface. The semiconductor substrate 300 may be a region including a semiconductor material (e.g., silicon (Si), silicon carbide (SiC), gallium arsenide (GaAs), etc.). Predetermined pixel transistors (not shown) and floating diffusion regions (not shown) may be disposed near the front surface.

Each of the plurality of photoelectric conversion elements 310 may be disposed in an active pixel (APX) or an optical black pixel (BPX). Each of the plurality of photoelectric conversion elements 310 may be implemented as a photodiode, a phototransistor, a photogate, or a combination thereof. For ease of explanation and better understanding of the disclosed technology, an embodiment in which the photoelectric conversion element 310 is implemented as a photodiode will be illustrated and described by way of example, with reference to the attached drawings. The photoelectric conversion element 310 may be a region that generates photocharges in response to incident light. The photoelectric conversion element 310 may be a region that includes the semiconductor material. The photoelectric conversion element 310 may be a region that further includes impurities of the first conductivity type (e.g., N-type).

The semiconductor region 320 may be a region that surrounds each of the plurality of photoelectric conversion elements 310. The semiconductor region 320 may be a region that includes the semiconductor material. The semiconductor region 320 may be a region that further includes impurities of the second conductivity type (e.g., P-type).

The pixel isolation structure 330 may be disposed outside the active pixel (APX) or the optical black pixel (BPX). For example, the pixel isolation structure 330 may be disposed near a boundary between two adjacent active pixels (APXs). The pixel isolation structure 330 may be disposed near a boundary between two adjacent optical black pixels (BPXs). The pixel isolation structure 330 may be disposed near a boundary between the active pixel (APX) and the optical black pixel (BPX) adjacent to each other.

The pixel isolation structure 330 may include a predetermined conductive layer and an insulation layer surrounding the conductive layer. The conductive layer may include, for example, polysilicon. A predetermined bias voltage may be applied to the conductive layer. When the bias voltage is applied to the conductive layer, the dark current of the active pixel (APX) may decrease. The insulation layer may include, for example, any one of silicon oxide, silicon nitride, or silicon oxynitride. The insulation layer may physically separate the conductive layer and the semiconductor region 320 from each other. The pixel isolation structure 330 may prevent light having penetrated the back surface of the semiconductor substrate 300 from being incident upon an adjacent pixel, resulting in reduction in crosstalk.

For example, the pixel isolation structure 330 may extend from the front surface of the semiconductor substrate 300 in a direction opposite to a third direction (Z). In some implementations, the pixel isolation structure 330 may have a structure that extends from the front surface to the back surface to penetrate the semiconductor substrate 300. In another example, the pixel isolation structure 330 may extend from the back surface in the third direction (Z). The pixel isolation structure 330 may have a structure that extends from the back surface to the front surface to penetrate the semiconductor substrate 300.

The anti-reflection region 400 may be a region that allows incident light to pass through the back surface of the semiconductor substrate 300 without being reflected therefrom. The anti-reflection region 400 may include a structure in which at least one insulation layer is stacked. For example, the anti-reflection region 400 may include a first anti-reflection layer 410 and a second anti-reflection layer 420. The anti-reflection region 400 may compensate for a difference in refractive index between a first optical coating layer (OC1) and the semiconductor substrate 300 so that light passing through the first optical coating layer (OC1) may be effectively incident into the semiconductor substrate 300.

The first anti-reflection layer 410 may be disposed on the back surface of the semiconductor substrate 300. The first anti-reflection layer 410 may be disposed across the active pixel array 131 as well as the optical black pixel array 132. The first anti-reflection layer 410 may include at least one of silicon oxide, silicon nitride, aluminum oxide, hafnium oxide, tantalum oxide, or a stacked structure thereof.

The second anti-reflection layer 420 may be disposed on the first anti-reflection layer 410. The second anti-reflection layer 420 may include at least one of silicon oxide, silicon nitride, aluminum oxide, hafnium oxide, tantalum oxide, or a stacked structure thereof.

The light guide layer (LG) may include a light blocking structure 500, a first capping layer 610, a first support layer 710, a first air region (AR1), and a first optical coating layer (OC1). The light guide layer (LG) may include a plurality of first air grid structures (AG1). The light guide layer (LG) may be a structure that guides incident light that is selectively transmitted through each active pixel (APX) onto the photoelectric conversion element 310 included in the active pixel (APX), while preventing light from entering an adjacent active pixel (APX) by using the light filter layer (LF).

The light blocking structure 500 may be disposed on the anti-reflection region 400. The light blocking structure 500 may be disposed in the optical black pixel array 132. The light blocking structure 500 may be a structure that blocks light incident upon the optical black pixel array 132 from being incident upon the photoelectric conversion element 310 of each of the plurality of optical black pixels (BPXs). The light blocking structure 500 may include a material having a high light absorption rate. For example, the light blocking structure 500 may include a metal material (e.g., tungsten).

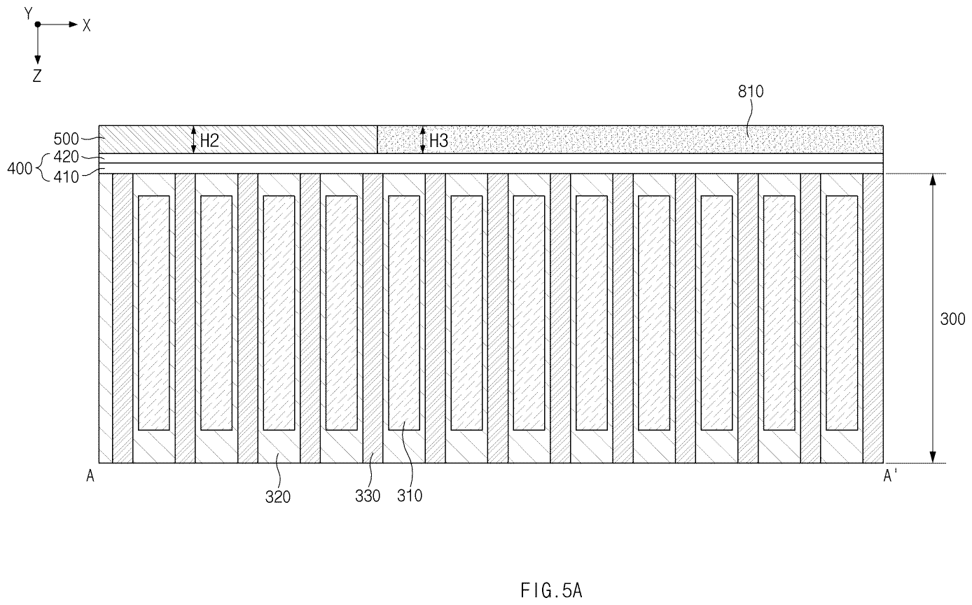

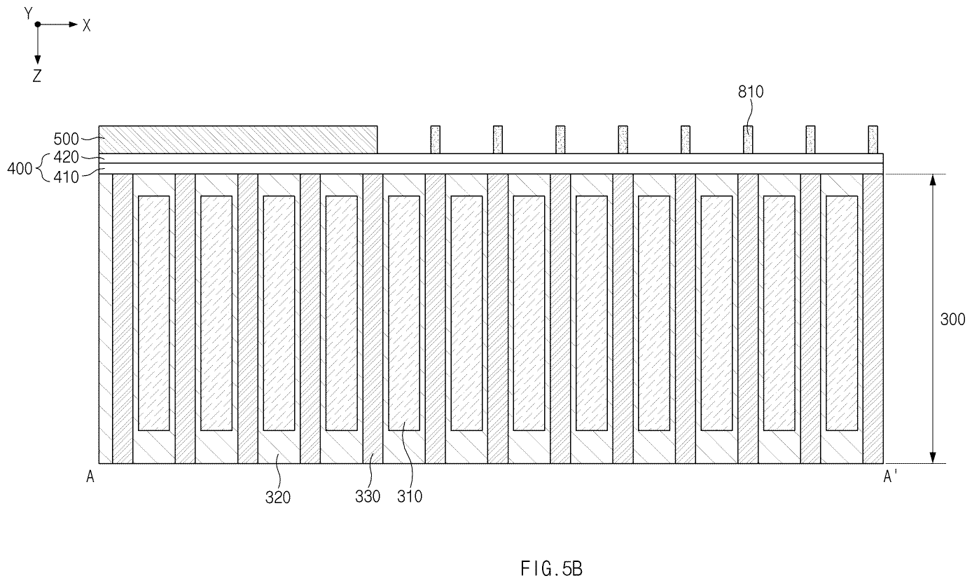

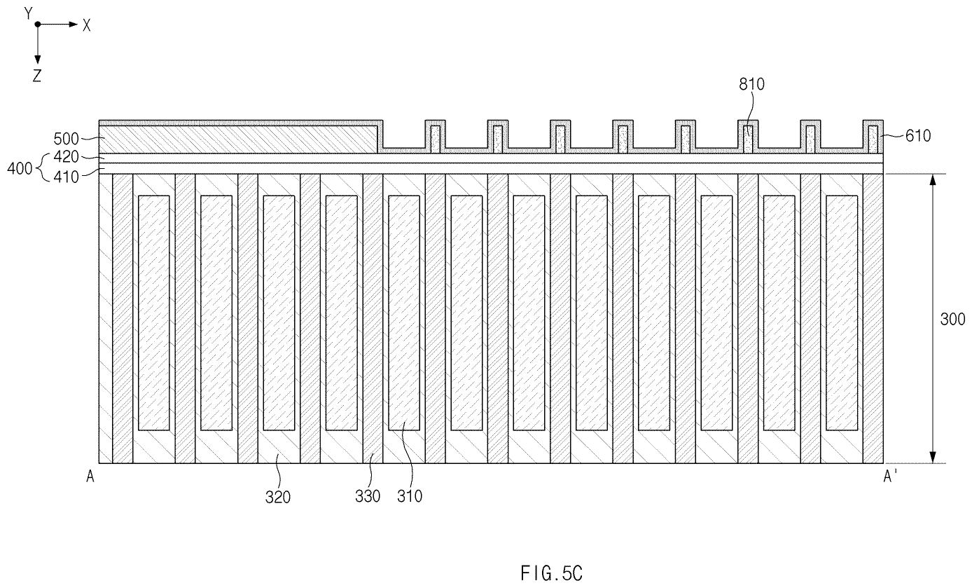

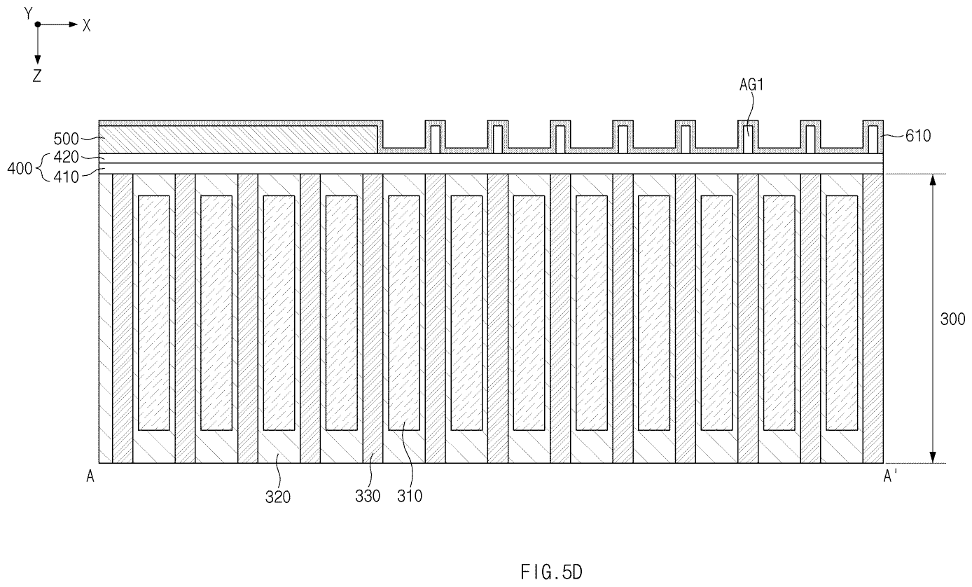

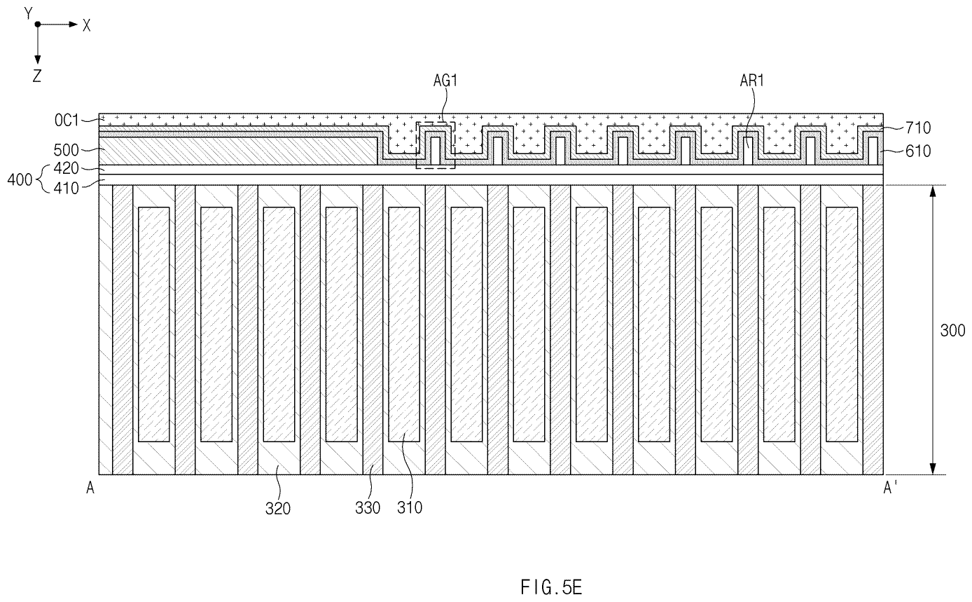

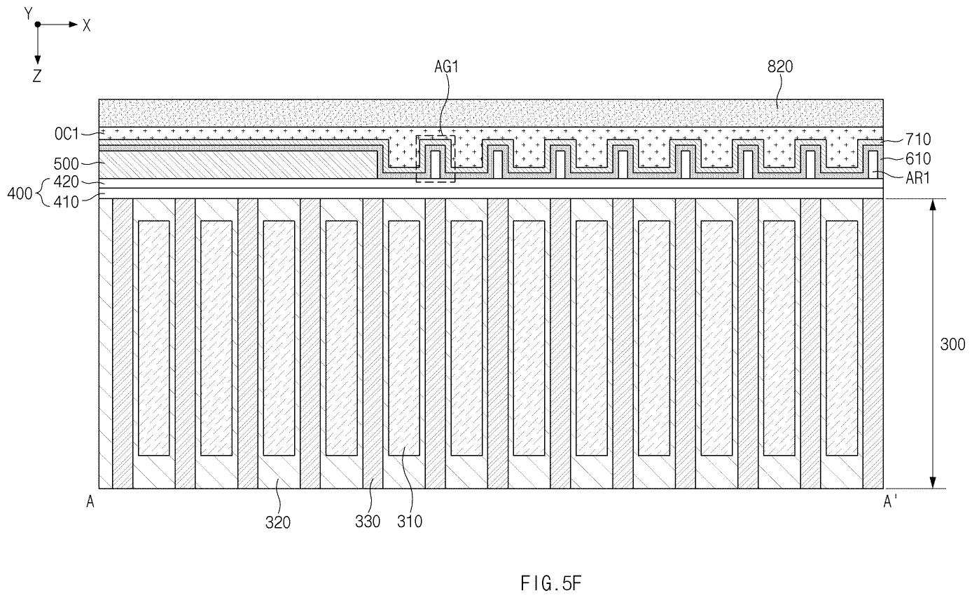

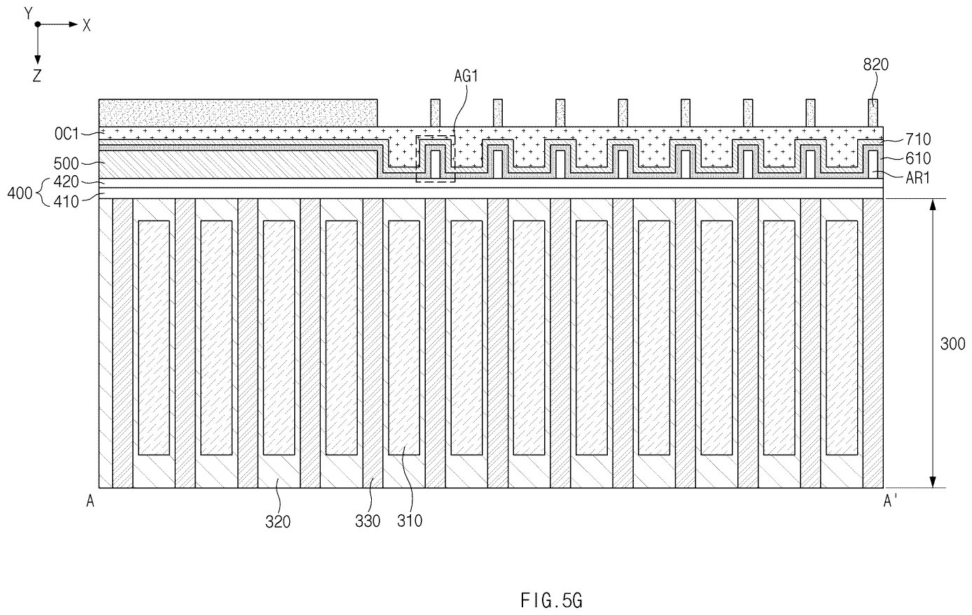

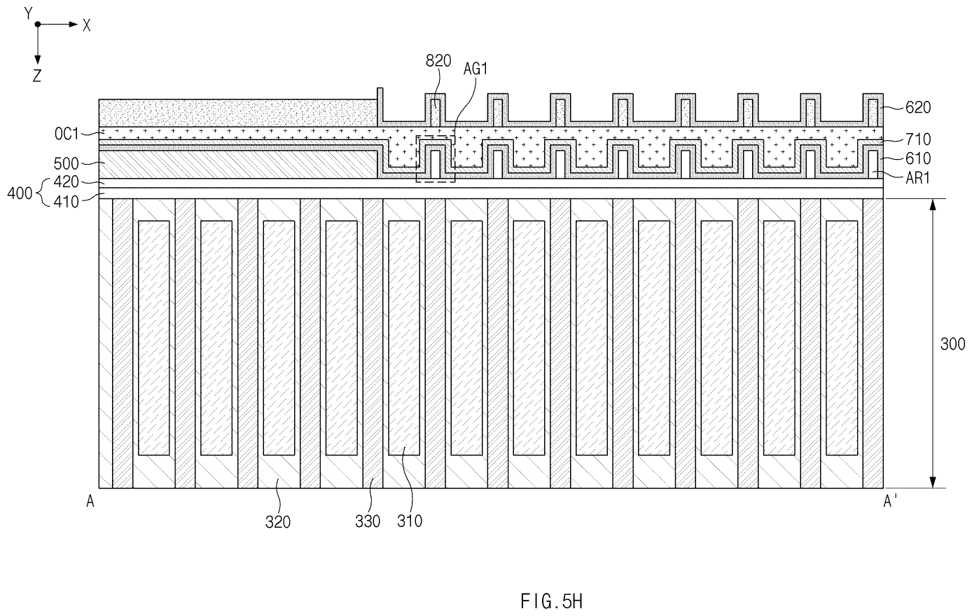

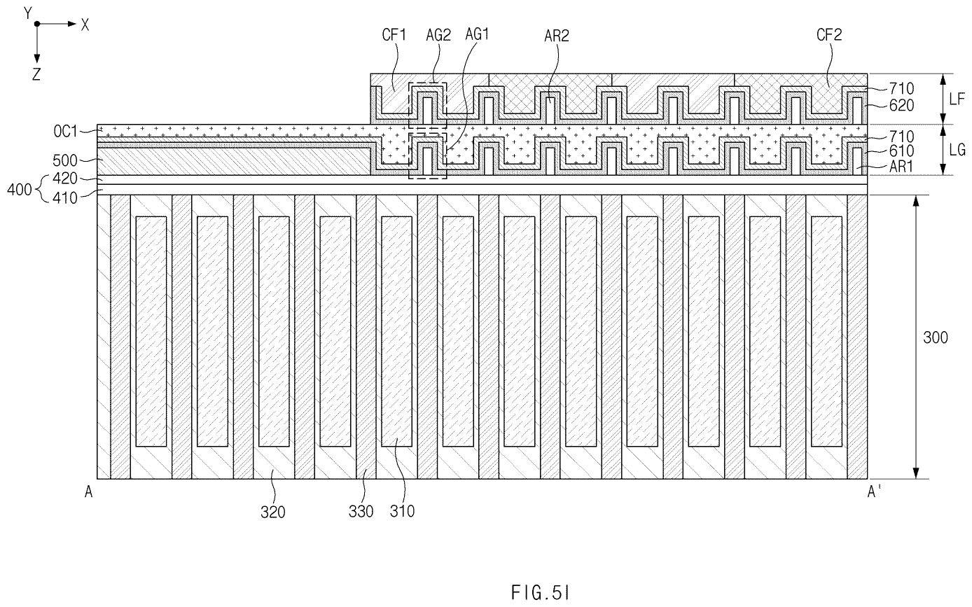

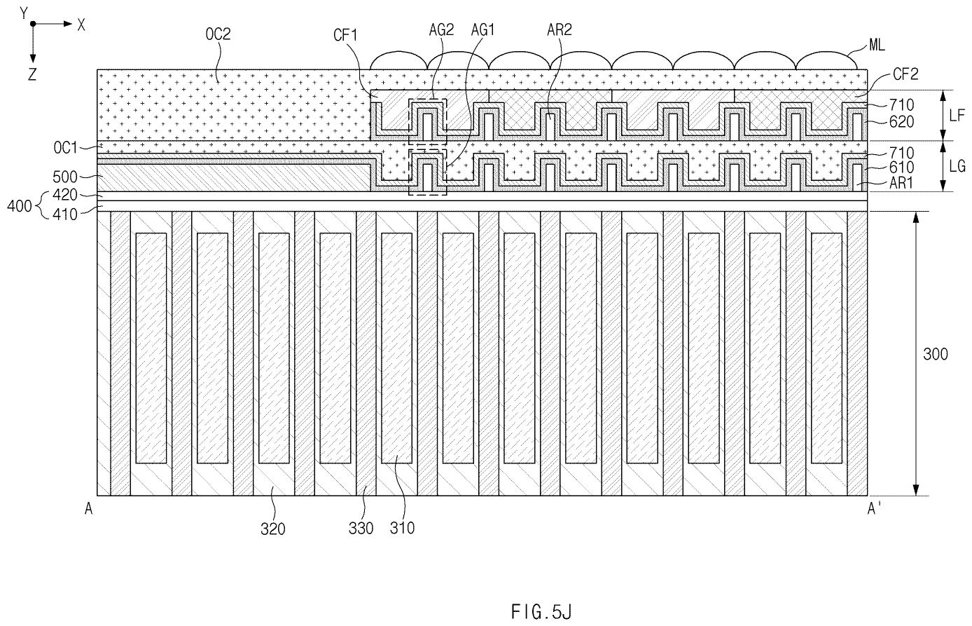

A first capping layer 610 may be disposed on the light blocking structure 500. The first capping layer 610 may be formed along a side surface of the light blocking structure 500. The first capping layer 610 may be formed along a side surface and a top surface of each of the plurality of first air regions (AR1). The first capping layer 610 may be disposed on the anti-reflection region 400 between the light blocking structure 500 and the first air region (AR1). The first capping layer 610 may be disposed on the anti-reflection region 400 between two adjacent first air regions (AR1). The first capping layer 610 may serve to define the boundaries of the plurality of first air regions (AR1) and to structurally support and maintain their shapes, such that the first air regions (AR1) can be formed and stably retained. As will be described later with reference to FIG. 5C, the first capping layer 610 may include a material (e.g., ultra-low temperature oxide ULTO) from which a sacrificial layer is easily removed in a subsequent plasma process for forming the first air region (AR1). For example, the first capping layer 610 may include at least one of silicon oxide, silicon nitride, aluminum nitride, titanium oxide, hafnium oxide, zirconium oxide, tin oxide, and magnesium oxide. In some implementations, although the first capping layer 610 has a smaller thickness than the first support layer 710, other implementations are also possible. The thickness of the first capping layer 610 may be sufficiently thin to allow the sacrificial layer to be easily removed in the plasma process.

The first support layer 710 may be disposed on the first capping layer 610. The first support layer 710 may be formed to surround the first capping layer 610. The thickness of the first support layer 710 may be sufficient to stably support the shape of the first air grid structure (AG1), because it may be difficult to maintain the shape of the first air grid structure (AG1) using only the first capping layer 610, which is formed with a reduced thickness to enable the sacrificial layer to be effectively discharged to the outside during the plasma process. For example, the thickness of the first support layer 710 may be larger than the thickness of the first capping layer 610, but the scope of the embodiment of the disclosed technology is not limited thereto.

The first air region (AR1) may be a region filled with air having a relatively low refractive index (e.g., 1). The refractive index of the first air region (AR1) may be lower than the refractive index of each of the first capping layer 610 and the first support layer 710. The shape of each of the plurality of first air regions (AR1) may be defined by the first capping layer 610. Since the refractive index of the first air region (AR1) is lower than the refractive indices of the peripheral elements, incident light obliquely incident toward the first air grid structure (AG1) may be prevented from entering the adjacent pixel (e.g., the active pixel APX) by the first air region (AR1). As a result, crosstalk within the active pixel array 131 may be reduced by the first air region (AR1).

The first optical coating layer (OC1) may be disposed between two adjacent first air grid structures (AG1). For example, the first optical coating layer (OC1) may be disposed between two first air grid structures (AG1) disposed at opposite edges of the active pixel (APX). The first optical coating layer (OC1) may be disposed on the two first air grid structures (AG1). The first optical coating layer (OC1) may extend in the first direction (X) and/or the second direction (Y) by a predetermined thickness over the first air grid structure (AG1) and the light blocking structure 500. The predetermined thickness may refer to a distance in the third direction (Z) between the first air grid structure (AG1) and the second air grid structure (AG2) to be described below. In another embodiment of the disclosed technology, the second air grid structure (AG2) may also be formed directly on the top surface of the first air grid structure (AG1) without the predetermined thickness.

The first optical coating layer (OC1) may serve as a planarization layer to compensate for a step difference that may occur by the plurality of first air grid structures (AG1) and the light blocking structure 500. The refractive index of the first optical coating layer (OC1) may be higher than the refractive indices of the first support layer 710 and the first capping layer 610. The first optical coating layer (OC1) may include a material that can suppress flare characteristics by preventing irregular or diffuse reflection of incident light. For example, the first optical coating layer (OC1) may include at least one of a polymer organic material such as a polyimide-based resin, a polystyrene-based resin, an acrylic-based resin, and an epoxy-based resin, or an inorganic material such as silicon oxide.

The first air grid structure (AG1) may include a first air region (AR1), a first capping layer 610, and a first support layer 710. A plurality of first air grid structures (AG1) may be repeatedly spaced apart from each other and arranged in the first direction (X). Each of the plurality of first air grid structures (AG1) may be disposed on a boundary between two active pixels (APX) that are adjacent to each other on the back surface of the semiconductor substrate 300. The height (H1) of the first air region (AR1) may be the same as the height (H2) of the light blocking structure 500, although this may vary depending on process variables and limitations. The top surface of the first air region (AR1) may be on the same horizontal plane (HP) as a top surface of the light blocking structure 500, such that there is no step difference between them. The height (H1) of the first air region (AR1) may be defined as a distance from the top surface of the anti-reflection region 400 to the top surface of the first air region (AR1). In some embodiments of the disclosed technology, the first air region (AR1) and the light-blocking structure 500 may be formed such that there is no step difference between the top surface of the first air region (AR1) and the top surface of the light-blocking structure 500.

Although not illustrated in FIG. 3, when the plurality of active pixels (APXs) is arranged in an (M×N) matrix configuration (where each of M and N is an integer greater than or equal to 2), the first air grid structure (AG1) may be disposed in a grid shape along the boundary between the plurality of active pixels (APX) when viewed in a plane (when viewed in the third direction Z). In addition, although not illustrated in FIG. 3, the first air grid structure (AG1) may include a predetermined metal layer (e.g., tungsten) disposed on the bottom surface of the first air region (AR1).

The light filter layer (LF) may include a second capping layer 620, a second support layer 720, a second air region (AR2), a first color filter (CF1), a second color filter (CF2), and a second optical coating layer (OC2). The light filter layer (LF) may further include a second air grid structure (AG2). The light filter layer (LF) may be a structure that selectively transmits light having a wavelength range targeted for each active pixel (APX) among incident light transmitted through the microlens (ML).

The second capping layer 620 may be disposed on the first optical coating layer (OC1). The second capping layer 620 may be formed on the active pixel array 131. The second capping layer 620 may be formed along the side and top surfaces of each of the plurality of second air regions (AR2). The second capping layer 620 may be disposed on the first optical coating layer (OC1) between two adjacent second air regions (AR2). The second capping layer 620 may serve to define the boundaries of the plurality of second air regions (AR2) and to structurally support and maintain their shapes, such that the first air regions (AR1) can be formed and stably retained. As will be described later with reference to FIG. 5H, the second capping layer 620 may include a material (e.g., ultra-low temperature oxide ULTO) from which a sacrificial layer is easily removed in a subsequent plasma process for forming the second air regions (AR2). For example, the second capping layer 620 may include at least one of silicon oxide, silicon nitride, aluminum nitride, titanium oxide, hafnium oxide, zirconium oxide, tin oxide, and magnesium oxide. In some implementations, although the second capping layer 620 has a smaller thickness than the second support layer 720, other implementations are also possible. The thickness of the second capping layer 620 may be sufficiently thin to facilitate removal of the sacrificial layer during the plasma process.

In another embodiment, a predetermined light blocking layer may be disposed on the optical black pixel array 132 within the light filter layer (LF), and a second capping layer 620 may also be disposed to cover an upper portion of the predetermined light blocking layer. In some embodiments of the disclosed technology, as illustrated in FIG. 3, the optical black pixel array 132 does not have a predetermined light blocking layer, and the second optical coating layer (OC2) is formed in the optical black pixel array 132, as will be described as an example.

The second support layer 720 may be disposed on the second capping layer 620. The second support layer 720 may be formed to surround the second capping layer 620. The second support layer 720 may be disposed within the active pixel array 131. The thickness of the second support layer 720 may be sufficient to stably support the shape of the second air grid structure (AG2) because it may be difficult to maintain the shape of the second air grid structure (AG2) using only the second capping layer 620, which is formed with a reduced thickness to allow the sacrificial layer to be effectively discharged to the outside during the plasma process. For example, although the second support layer 720 may be thicker than the second capping layer 620, other implementations are also possible.

The second air region (AR2) may be a region filled with air having a relatively low refractive index (e.g., 1). The refractive index of the second air region (AR2) may be lower than the refractive indices of the second capping layer 620 and the second support layer 720. The shape of each of the plurality of second air regions (AR2) may be defined by the second capping layer 620. The top and side surfaces of the second air region (AR2) may be covered by the second capping layer 620. For example, the bottom surface of the second air region (AR2) may contact the first optical coating layer (OC1). Although not illustrated in FIG. 3, the bottom surface of the second air region (AR2) may include, for example, a predetermined metal layer (not shown) (e.g., tungsten). Since the refractive index of the second air region (AR2) is lower than the refractive index of the peripheral elements, incident light obliquely incident toward the second air grid structure (AG2) may be prevented from being incident upon the adjacent pixel (e.g., the active pixel APX) by the second air region (AR2). As a result, crosstalk within the active pixel array 131 may be reduced by the second air region (AR2).

The first color filter (CF1) may be disposed between two adjacent second air grid structures (AG2). For example, the first color filter (CF1) may be disposed between two second air grid structures (AG2) arranged on the opposite edges of the active pixel (APX). The first color filter (CF1) may be formed to be higher than the second air grid structure (AG2). The first color filter (CF1) may selectively transmit light (e.g., green light) of a first wavelength range (e.g., 500 nm to 600 nm) among incident light. The active pixel (APX) including the first color filter (CF1) may be a pixel that detects light of the first wavelength range and generates a pixel signal.

The second color filter (CF2) may be disposed between two adjacent second air grid structures (AG2). For example, the second color filter (CF2) may be disposed between two second air grid structures (AG2) arranged on the opposite edges of the active pixel (APX). The second color filter (CF2) may be formed to be higher than the second air grid structure (AG2). The second color filter (CF2) may selectively transmit light (e.g., blue light of 400 nm to 500 nm or red light of 600 nm to 700 nm) among incident light. The active pixel (APX) including the second color filter (CF2) may be a pixel that detects light of the second wavelength range and generates a pixel signal.

FIG. 3 illustrates the active pixel array 131 including a quad-Bayer pattern, and illustrates a cross-sectional view of a portion of the quad-Bayer pattern taken along the line A-A′. In FIG. 3, two identical first color filters (CF1) may be disposed to be in contact with each other in the first direction (X), and two identical second color filters (CF2) may be disposed to be in contact with each other in the first direction (X). In an example embodiment, the active pixel array 131 includes a Bayer pattern. In this case, the first color filter (CF1) may be adjacent to the second color filter (CF2). The first color filters (CF1) and the second color filters (CF2) may be alternately and repeatedly arranged in the first direction (X).

The refractive index of each of the first color filter (CF1) and the second color filter (CF2) may be higher than the refractive index of the second capping layer 620 and the second support layer 720.

The second optical coating layer (OC2) may be disposed on the first color filter (CF1) and the second color filter (CF2) in the active pixel array 131. The second optical coating layer (OC2) may be disposed on the second air grid structure (AG2). The second optical coating layer (OC2) may extend in the first direction (X) and/or the second direction (Y) by a predetermined thickness over the first color filter (CF1) and the second color filter (CF2). The predetermined thickness may refer to a separation distance in the third direction (Z) between the microlens (ML) and any one of the first color filter (CF1) and the second color filter (CF2).

The second optical coating layer (OC2) may be disposed on the first optical coating layer (OC1) in the optical black pixel array 132. In some implementations, the top surface of the second optical coating layer (OC2) in the optical black pixel array 132 may be formed to be higher than top surfaces of the first color filter (CF1) and the second color filter (CF2). The second optical coating layer (OC2) may extend over the light blocking structure 500 in the optical black pixel array 132, and may be spaced apart from the light blocking structure 500.

The second optical coating layer (OC2) may include a material that can suppress flare characteristics by preventing irregular or diffuse reflection of incident light. For example, the second optical coating layer (OC2) may include at least one of a polymer organic material such as a polyimide-based resin, a polystyrene-based resin, an acrylic-based resin, and an epoxy-based resin, or an inorganic material such as silicon oxide.

The second air grid structure (AG2) may include a second air region (AR2), a second capping layer 620, and a second support layer 720. The plurality of second air grid structures (AG2) may be repeatedly spaced apart from each other and disposed in the first direction (X). The plurality of second air grid structures (AG2) may be disposed at boundaries between two adjacent active pixels (APX) on the first optical coating layer (OC1). Although the height of the second air region (AR2) may be the same as the height (H1) of the first air region (AR1), other implementations are also possible. The second air grid structure (AG2) may overlap the first air grid structure (AG1) when viewed in the third direction (Z). The second air grid structure (AG2) may be disposed on the first air grid structure (AG1).

Although not illustrated in FIG. 3, when the plurality of active pixels (APXs) is arranged in an (M×N) matrix configuration (where each of M and N is an integer greater than or equal to 2), the second air grid structure (AG2) may be in a grid shape such that a plurality of second air grid structures are arranged along the boundaries between the plurality of active pixels (APX) when viewed in a plane (when viewed in the third direction Z).

The microlens (ML) may be disposed on the second optical coating layer (OC2). Each of the plurality of microlenses (ML) may be disposed within the active pixel (APX). The microlens (ML) may have a hemispherical surface. The microlens (ML) may converge light incident from the outside onto the active pixel (APX). The plurality of microlenses (ML) may include at least one of a polymer organic material such as a polyimide-based resin, a polystyrene-based resin, an acrylic-based resin, an epoxy-based resin, or an inorganic material such as silicon oxide.

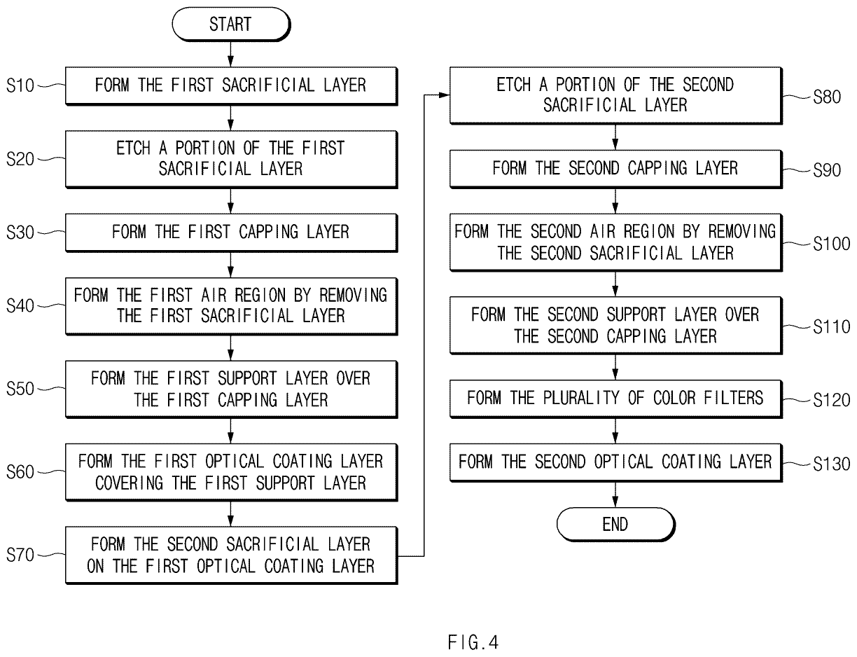

FIG. 4 is a flowchart illustrating an example of a method for manufacturing the image sensing device 10 shown in FIG. 1 based on some embodiments of the disclosed technology.

FIGS. 5A to 5J are cross-sectional views illustrating examples of a method for manufacturing the image sensing device 10 shown in FIG. 1 based on some embodiments of the disclosed technology.

Referring to FIGS. 3 and 5A, a plurality of photoelectric conversion elements 310 may be formed in the semiconductor substrate 300. The plurality of photoelectric conversion elements 310 may be formed by, for example, a process of implanting impurities of the first conductivity type. Impurities of the second conductivity type may be implanted into the semiconductor region 320.

A trench recessed from the front surface or the back surface of the semiconductor substrate 300 toward the inside of the semiconductor substrate 300 may be formed, and a pixel isolation structure 330 may be formed in the trench. For example, a predetermined insulation layer may be formed along an inner wall of the trench, and the remaining trench after formation of the insulation layer may be gap-filled with a predetermined conductive layer such as polysilicon, resulting in formation of the pixel isolation structure 330.

A first anti-reflection layer 410 may be formed on the back surface of the semiconductor substrate 300 (e.g., the top surface of the semiconductor substrate 300 in FIG. 5A). A second anti-reflection layer 420 may be formed on the first anti-reflection layer 410. Thereafter, a light blocking structure 500 may be formed on the second anti-reflection layer 420 in a region corresponding to the optical black pixel array 132 described with reference to FIG. 3.

Referring to FIGS. 4 and 5A, a first sacrificial layer 810 may be formed in the active pixel array 131 shown in FIG. 3 (operation S10). The first sacrificial layer 81 may include at least one of carbon-containing spin-on-carbon (SOC) or silicon oxynitride. The height (H3) of the first sacrificial layer 810 may be the same as the height (H2) of the light blocking structure 500, although this may vary depending on process variables and limitations. When the height (H3) of the first sacrificial layer 810 is formed to be the same as the height (H2) of the light blocking structure 500, the first air grid structure (AG1) and the second air grid structure (AG2) may be formed to have a uniform thickness throughout the pixel array 130 (see FIG. 2) in a subsequent process of forming each of the light guide layer (LG) (see FIG. 3) and the light filter layer (LF) (see FIG. 3).

Referring to FIGS. 4 and 5B, a portion of the first sacrificial layer 810 may be etched (operation S20). The first sacrificial layer 810 may be removed except for a portion for forming the first air region (AR1). In some implementations, a height of the remaining first sacrificial layer 810 may also be maintained at a third height (H3).

Referring to FIGS. 4 and 5C, a first capping layer 610 may be formed (operation S30). The first capping layer 610 may be formed to surround the top and side surfaces of the first sacrificial layer 810. The first capping layer 610 may be formed to cover the top surface of the anti-reflection region 400 between the first sacrificial layers 810 adjacent to each other. The first capping layer 610 may be further formed along the top and side surfaces of the light blocking structure 500. The first capping layer 610 may be formed to have a thickness such that the first sacrificial layer 810 can be sufficiently removed in a subsequent plasma process.

Referring to FIGS. 4 and 5D, the first sacrificial layer 810 may be removed to form the first air region (AR1) (operation S40). The first sacrificial layer 810 may be removed by a plasma process (e.g., a primary plasma process). Here, the plasma process may include a plasma process that is performed using at least one of oxygen, nitrogen, hydrogen, carbon monoxide, carbon dioxide, and methane. In an implementation, when a plasma process is performed using oxygen gas, oxygen radicals may be introduced into the first sacrificial layer 810 through the first capping layer 610. The oxygen radicals may be combined with carbons of the first sacrificial layer 810 to generate carbon monoxide (CO) gas or carbon dioxide (CO₂) gas. The carbon monoxide (CO) gas or carbon dioxide (CO₂) gas may be discharged outside through the first capping layer 610. As a result, the first sacrificial layer 810 may be removed, and the first air region (AR1) may be formed at the position from which the first sacrificial layer 810 is removed.

Referring to FIGS. 4 and 5E, the first support layer 710 may be formed on the first capping layer 610 (operation S50). After the plasma process is completed, the first support layer 710 may be formed on the first capping layer 610. The first support layer 710 may be formed to be relatively thicker than the first capping layer 610, but the disclosed technology is not limited thereto. The first support layer 710 may be formed to a thickness necessary to stably maintain the shape of the first air grid structure (AG1).

Thereafter, the first optical coating layer (OC1) covering the first support layer 710 may be formed (operation S60). The first optical coating layer (OC1) may be formed to fill a region between the first air grid structures (AG1) (e.g., a region between the first support layers 710). The first optical coating layer (OC1) may be formed on the first support layer 710. The first optical coating layer (OC1) may be formed to be higher than the top surface of the first support layer 710. After the first optical coating layer (OC1) is formed, a planarization process may be performed on the top surface of the first optical coating layer (OC1). When the planarization process is performed, the top surface of the first optical coating layer (OC1) may be formed to be spaced apart from the top surface of the first support layer 710. According to another embodiment, the top surface of the first optical coating layer (OC1) may be formed to be identical to the top surface of the first support layer 710.

Referring to FIGS. 4 and 5F, a second sacrificial layer 820 may be formed on the first optical coating layer (OC1) (operation S70). Although the second sacrificial layer 820 is formed to have the same height as the height (H3) of the first sacrificial layer 810, other implementations are also possible. For example, the second sacrificial layer 820 may also be formed to have a height different from that of the first sacrificial layer 810.

Referring to FIGS. 4 and 5G, a portion of the second sacrificial layer 820 may be etched (operation S80). The second sacrificial layer 820 may be removed except for a portion for forming the second air region (AR2).

Referring to FIGS. 4 and 5H, the second capping layer 620 may be formed (operation S90). The second capping layer 620 may be formed to surround the top and side surfaces of the second sacrificial layer 820. The second capping layer 620 may be formed to cover the top surface of the first optical coating layer (OC1) between the second sacrificial layers 820 adjacent to each other. The second capping layer 620 may be further formed along the side surface of the light blocking structure 500. The second capping layer 620 may be formed to have a predetermined thickness such that the second sacrificial layer 820 can be removed in a subsequent plasma process.

Referring to FIGS. 4 and 5I, the second sacrificial layer 820 may be removed to form the second air region (AR2) (operation S100). The second sacrificial layer 820 may be removed by a plasma process (i.e., a second plasma process). Here, the plasma process may be a plasma process including at least one gas from among oxygen, nitrogen, hydrogen, carbon monoxide, carbon dioxide, and methane. As described in the first plasma process, the second plasma process may also be performed, and through this process, the second sacrificial layer 820 may be removed, and the second air region (AR2) may be formed at the removed position.

Thereafter, the second support layer 720 may be formed on the second capping layer 620 (operation S110). After the plasma process is completed, the second support layer 720 may be formed on the second capping layer 620. The second support layer 720 may be formed to be relatively thicker than the second capping layer 620, but the disclosed technology is not limited thereto. The second support layer 720 may be formed to a thickness necessary to stably maintain the shape of the second air grid structure (AG2).

Thereafter, the plurality of color filters (CF1, CF2) may be formed (operation S120). The plurality of color filters (CF1, CF2) may be formed on the second support layer 720. Each of the plurality of color filters (CF1, CF2) may be formed to fill a region between the second air grid structures (AG2). The plurality of color filters may be formed in various patterns. For example, according to the Bayer pattern having a (2×2) matrix configuration, two color filters (hereinafter referred to as “green color filters”) that selectively transmit light in a wavelength range corresponding to green light may be arranged in a diagonal direction in the (2×2) matrix configuration, and a color filter (hereinafter referred to as a red color filter) that selectively transmits light in a wavelength range corresponding to red light and another color filter (hereinafter referred to as a blue color filter) that selectively transmits light in a wavelength range corresponding to blue light may be arranged in opposite diagonal directions in the (2×2) matrix configuration. According to a quad-Bayer pattern having a (4×4) matrix configuration, two groups of four green color filters arranged in the (2×2) matrix configuration may be arranged diagonally from each other in the (4×4) matrix configuration, a group of four red color filters arranged in the (2×2) matrix configuration and a group of four blue color filters arranged in the (2×2) matrix configuration may be arranged in opposite diagonal directions from each other. In addition, a plurality of color filters may be formed in the active pixel array 131 in various patterns.

Referring to FIGS. 4 and 5J, the second optical coating layer (OC2) may be formed (operation S130). The second optical coating layer (OC2) may be formed to cover the top surfaces of the plurality of color filters. The second optical coating layer (OC2) may be formed on the first optical coating layer (OC1) in a region where the plurality of color filters is not formed. After the second optical coating layer (OC2) is formed, a planarization process may be performed on the top surface of the second optical coating layer (OC2).

Thereafter, a plurality of microlenses (ML) may be formed on the second optical coating layer (OC2). Each of the plurality of microlenses (ML) may be formed by arranging a predetermined lens material particle on the second optical coating layer (OC2) so as to overlap the center of each active pixel (APX), and then performing a heat treatment process such that the top surface of the lens material particle has a hemispherical surface.

The light blocking structure 500 is formed on the optical black pixel array 132, so that a step is formed on the anti-reflection region 400 of the active pixel array 131 and the optical black pixel array 132. As a result, when the sacrificial layer for forming the air grid structure is formed in a situation where the step exists on the anti-reflection region 400, the sacrificial layer is formed to be thicker in the active pixels (APX) adjacent to the optical black pixel array 132. Therefore, there may occur a problem in which the sacrificial layer is not properly removed in the operation (S20) of removing the sacrificial layer and thus patterning is not performed. If such patterning is not performed properly, there may occur a problem in which it is difficult to form the air grid structure.

However, in some embodiments of the disclosed technology, when the height (H3) of the first sacrificial layer 810 is formed to be the same as the height (H2) of the light blocking structure 500, the step difference can be eliminated, so that the air grid structure can be formed evenly in the active pixels (APX) adjacent to the optical black pixel array 132 in the same manner as in the active pixels (APX) located at the center of the active pixel array 131. In addition, as the light guide layer (LG) including the air grid structure is formed, light having penetrated the color filter may be guided to the photoelectric conversion element 310 of the corresponding active pixel, so that quantum efficiency can increase and crosstalk can be reduced.

As is apparent from the above description, some embodiments of the disclosed technology may provide an image sensing device in which an air grid structure can be uniformly formed even in an active pixel array portion adjacent to the optical black pixel array. Some embodiments of the disclosed technology may also provide a method for manufacturing such an image sensing device.

Some embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
an active pixel array region including an active pixel array of pixels;
an optical black pixel array region disposed adjacent to the active pixel array and including an optical black pixel array of pixels;
a light guide layer including: one or more first air grid structures disposed in the active pixel array region; and a light blocking structure disposed in the optical black pixel array region; and
a light filter layer including a second air grid structure that overlaps the one or more first air grid structures and disposed between a plurality of color filters, and disposed on the light guide layer,
wherein each first air grid structure includes an air region that is filled with air and surrounded by a material layer,
wherein a height of the air region is equal to a height of the light blocking structure.

2. The image sensing device according to claim 1, wherein the light guide layer further includes:
a first optical coating layer disposed between the one or more first air grid structures.

3. The image sensing device according to claim 2, wherein:
the first optical coating layer is further arranged on the one or more first air grid structures, and further extends above the light blocking structure.

4. The image sensing device according to claim 3, wherein:
the second air grid structure is formed to be in contact with a top surface of the first optical coating layer.

5. The image sensing device according to claim 3, wherein the light filter layer further includes:
a second optical coating layer in contact with a top surface of the first optical coating layer within the optical black pixel array and in contact with a top surface of each of the plurality of color filters within the active pixel array.

6. The image sensing device according to claim 2, wherein the material layer of the one or more first air grid structures includes:
a capping layer formed to surround a top surface and side surfaces of the air region,
wherein the capping layer extends to be in contact with a top surface and side surfaces of the light blocking structure.

7. The image sensing device according to claim 6, wherein the material layer of the one or more first air grid structures further includes:
a support layer covering the top surface of the capping layer and thicker than the capping layer,
wherein the support layer extends along the top surface of the capping layer over the light blocking structure.

8. The image sensing device according to claim 6, wherein:
the first optical coating layer has a higher refractive index than that of the capping layer.

9. The image sensing device according to claim 1, wherein:
the one or more first air grid structures are disposed along one or more boundaries between a plurality of active pixels arranged in the active pixel array.

10. The image sensing device according to claim 1, wherein:
the light guide layer is disposed on a back surface of a semiconductor substrate including a photoelectric conversion element.

11. An image sensing device comprising:
a plurality of active pixels;
a plurality of first air grid structures disposed at boundaries between the plurality of active pixels and including a first air region that is filled with air and surrounded by a material layer;
a light blocking structure disposed at one side of the plurality of first air grid structures; and
a plurality of second air grid structures disposed at the boundaries between the plurality of active pixels and including a second air region that is filled with air and surrounded by a material layer, the plurality of second air grid structures being disposed over the plurality of first air grid structures,
wherein a top surface of the first air region is disposed on a same plane as a top surface of the light blocking structure.

12. The image sensing device according to claim 11, further comprising:
a first optical coating layer disposed between the plurality of first air grid structures arranged at the boundaries between the plurality of active pixels; and
a plurality of color filters, each color filter being disposed between the plurality of second air grid structures arranged at the boundaries between the plurality of active pixels.

13. The image sensing device according to claim 12, wherein:
the first optical coating layer is further disposed on the plurality of first air grid structures, and further extends above the light blocking structure.

14. The image sensing device according to claim 13, wherein:
the plurality of second air grid structures is formed to be in contact with a top surface of the first optical coating layer.

15. The image sensing device according to claim 12, further comprising:
a second optical coating layer formed to be in contact with top surfaces of the plurality of color filters,
wherein the second optical coating layer further extends above the light blocking structure.

16. The image sensing device according to claim 12, wherein each of the plurality of first air grid structures includes:
a first capping layer formed to surround a top surface and side surfaces of the first air region; and
a first support layer formed to cover a top surface of the first capping layer, the first support layer being thicker than the first capping layer, and
each of the plurality of second air grid structures includes:
a second capping layer formed to surround a top surface and side surfaces of the second air region; and
a second support layer formed to cover a top surface of the second capping layer, the second support layer being thicker than the second capping layer.

17. The image sensing device according to claim 16, wherein:
each of the first capping layer and the first support layer has a lower refractive index than that of the first optical coating layer; and
each of the second capping layer and the second support layer has a lower refractive index than that of the color filters.

18. The image sensing device according to claim 11, wherein:
the plurality of first air grid structures is disposed on a back surface of a semiconductor substrate including a photoelectric conversion element.

19. A method for manufacturing an image sensing device comprising:
forming a light blocking structure in an optical black pixel array and a first sacrificial layer having a same height as the light blocking structure in an active pixel array adjacent to the optical black pixel array;
etching a portion of the first sacrificial layer;
forming a first capping layer formed to surround a top surface and side surfaces of the etched first sacrificial layer;
forming at least one first support layer on the first capping layer;
forming an optical coating layer formed to cover the first support layer;
forming a second sacrificial layer on the optical coating layer;
etching a portion of the second sacrificial layer;
forming a second capping layer formed to surround a top surface and side surfaces of the etched second sacrificial layer;
forming a second air region by removing the second sacrificial layer; and
forming a second support layer on the second capping layer.

20. The method according to claim 19, wherein the forming the optical coating layer includes:
filling a region between the first support layers with the optical coating layer;
forming the optical coating layer to be higher than a top surface of the first support layer; and
planarizing a top surface of the optical coating layer.
